(19) United States
(12) Patent Application Publication
(10) Pub. No.: US 2024/0131532 A1
(43) Pub. Date: Apr. 25, 2024

(54) DISCHARGING DEVICE AND SUBSTRATE TREATING APPARATUS INCLUDING THE SAME

(71) Applicants: SEMES CO., LTD., Cheonan-si (KR); Samsung Electronics Co., Ltd., Suwon-si (KR)

(72) Inventors: Jong Han KIM, Cheonan-si (KR); Jin Uk SONG, Suwon-si (KR); Rae Taek OH, Cheonan-si (KR); Ji Ho KIM, Cheonan-si (KR); Ho Kyung KANG, Suwon-si (KR); Kwang Sung SON, Suwon-si (KR)

(73) Assignees: SEMES CO., LTD., Cheonan-si (KR); Samsung Electronics Co., Ltd., Suwon-si (KR)

(21) Appl. No.: 18/465,524

(22) Filed: Sep. 11, 2023

(30) Foreign Application Priority Data
Oct. 24, 2022 (KR) 10-2022-0138566

(51) Int. Cl. B05B 1/02

(52) U.S. Cl. CPC B05B 1/02

(57) ABSTRACT

According to at least one example embodiment, a substrate treating apparatus includes a substrate support structure including a spin head, the substrate support structure configured to support a substrate, and rotate the substrate, at least one treating liquid recovery container configured to recover at least one substrate treating liquid, and a discharging device including a first nozzle and a second nozzle, the first nozzle configured to discharge a chemical onto the substrate, and the second nozzle configured to discharge deionized water onto the substrate, wherein the first nozzle includes a surface pattern configured to provide roughness on an inner surface of the first nozzle.

### CROSS-REFERENCE TO RELATED APPLICATION

This U.S. non-provisional application claims the benefit of priority under 35 U.S.C. 119 to Korean Patent Application No. 10-2022-0138566 filed on Oct. 25, 2022 in the Korean Intellectual Property Office, the contents of which in its entirety are herein incorporated by reference.

### BACKGROUND

Various example embodiments of the inventive concepts relate to a discharging device, a substrate treating apparatus including the same, and/or a method of operating the discharging device. More specifically, one or more example embodiments of the inventive concepts relate to a discharging device utilized in a cleaning process and/or a substrate treating apparatus including the same, etc.

Semiconductor fabricating processes may be continuously performed within a semiconductor fabricating facility, and the fabricating processes may be divided into a pre-process and a post-process. The semiconductor fabricating facility may be installed within a semiconductor fabricating plant (hereinafter referred to as a “Fab”) in order to fabricate semiconductors.

The pre-process refers to a process of forming circuit patterns on a wafer to complete chips. The pre-process may include a deposition process of forming a thin film on the wafer, a photolithography process of transferring a photoresist onto the thin film using a photomask, an etching process of selectively removing undesired and/or unnecessary portions using a chemical material and/or a reactive gas in order to form desired circuit patterns on the wafer, an ashing process of removing the photoresist remaining after the etching process, an ion implantation process of implanting ions into portions connected to the circuit patterns to impart characteristics of an electronic element, a cleaning process of removing a contamination source on the wafer, and the like.

The post-process refers to a process of evaluating performance of a product fabricated through the pre-process. The post-process may include a primary inspection process of inspecting each wafer and determining whether or not each chip on the wafer operates properly, sorting the chips into good products and bad products, a package process of cutting and separating each chip through dicing, die bonding, wire bonding, molding, marking, etc., to form a shape of a product, a final inspection process of finally inspecting characteristics and reliability of the product through electrical characteristic inspection, burn-in inspection, etc., and the like.

Foreign materials remaining on a substrate are removed by sequentially using a chemical and deionized water (DIW) in a cleaning process, and moisture on the substrate is finally removed through a drying process.

When the moisture on the substrate is removed, a method of discharging isopropyl alcohol (IPA) onto the substrate to allow the moisture to be replaced with a component of the IPA has been used. However, even after the discharging of the IPA has been completed, the IPA remaining in a nozzle continuously flows down to a surface of the substrate, resulting in a situation in which the substrate is not completely dried and/or causes a problem wherein the time required for the substrate to completely dried is delayed and/or increased, etc.

### SUMMARY

Various example embodiments of the inventive concepts provide a discharging device including a nozzle capable of decreasing and/or decreasing and/or preventing a chemical from flowing down by having surface roughness formed on an inner surface thereof, and a substrate treating apparatus including the same.

However, the example embodiments of the inventive concepts are not restricted to those set forth herein. The above and other aspects of the example embodiments of the inventive concepts will become more apparent to one of ordinary skill in the art to which the inventive concepts pertain by referencing the detailed description of the example embodiments of the inventive concepts given below.

According to at least one example embodiment of the inventive concepts, there is provided a substrate treating apparatus. The substrate treating apparatus comprises: a substrate support structure including a spin head, the substrate support structure configured to support a substrate, and rotate the substrate; at least one treating liquid recovery container configured to recover at least one substrate treating liquid; a discharging device including a first nozzle and a second nozzle, the first nozzle configured to discharge a chemical onto the substrate; and the second nozzle configured to discharge deionized water onto the substrate, wherein the first nozzle includes a surface pattern configured to provide roughness on an inner surface of the first nozzle.

According to at least one example embodiment of the inventive concepts, there is provided a substrate treating apparatus. The substrate treating apparatus comprises: a discharging device including a first nozzle and a second nozzle, the discharging device configured to provide a substrate treating liquid onto a substrate through the first nozzle and the second nozzle, the first nozzle configured to discharge a chemical onto the substrate, and the second nozzle configured to discharge deionized water onto the substrate; and the first nozzle includes a surface pattern configured to provide surface roughness on an inner surface of the first nozzle, the surface pattern is on a portion of the inner surface of the first nozzle, and is formed at an end portion of the first nozzle adjacent to a discharge port or is formed at the end portion of the first nozzle and on a surface of the discharge port, and the surface pattern has a roughness value of 0.4 to 5.

According to at least one example embodiment of the inventive concepts, there is provided a discharging device configured to provide a substrate treating liquid for treating a substrate. The discharging unit comprises: a first nozzle configured to discharge a chemical onto a substrate; a second nozzle configured to discharge deionized water on the substrate; and the first nozzle includes a surface pattern configured to provide surface roughness is on an inner surface of the first nozzle.

It should be noted that the effects of one or more of the example embodiments of the inventive concepts are not limited to those described above, and other effects of the example embodiments of the inventive concepts will be apparent from the following description.

### BRIEF DESCRIPTION OF THE DRAWINGS

The above and other aspects and features of the example embodiments of the inventive concepts will become more apparent by describing in detail example embodiments thereof with reference to the attached drawings, in which:

FIG. 1 is a block diagram illustrating internal components of a substrate treating system utilized in a cleaning process according to at least one example embodiment.

FIG. 2 is an illustrative view schematically illustrating an internal structure of a substrate treating apparatus utilized in a cleaning process according to at least one example embodiment.

FIG. 3 is a first illustrative view for describing a relationship between an internal structure of the nozzle and a surface adhesive force of the chemical according to at least one example embodiment.

FIG. 4 is a second illustrative view for describing a relationship between an internal structure of the nozzle and a surface adhesive force of the chemical according to at least one example embodiment.

FIG. 5 is a first illustrative view schematically illustrating an internal structure of the nozzle according to at least one example embodiment of the inventive concepts.

FIG. 6 is a second illustrative view schematically illustrating an internal structure of the nozzle according to at least one example embodiment of the inventive concepts.

FIG. 7 is a third illustrative view schematically illustrating an internal structure of the nozzle according to at least one example embodiment of the inventive concepts.

FIG. 8 is a fourth illustrative view schematically illustrating an internal structure of the nozzle according to at least one example embodiment of the inventive concepts.

FIG. 9 is a fifth illustrative view schematically illustrating an internal structure of the nozzle according to at least one example embodiment of the inventive concepts.

FIG. 10 is a sixth illustrative view schematically illustrating an internal structure of the nozzle according to at least one example embodiment of the inventive concepts.

### DETAILED DESCRIPTION

Hereinafter, various example embodiments of the inventive concepts will be described in detail with reference to the accompanying drawings. The same components in the drawings will be denoted by the same reference numerals, and an overlapping description thereof will be omitted.

One or more of the example embodiments of the inventive concepts relate to a discharging unit discharging a chemical, a substrate treating apparatus including the same, and/or a method of operating the discharging unit, but the example embodiments are not limited thereto. The discharging unit includes a nozzle capable of decreasing and/or preventing a chemical from flowing down by having surface roughness formed on an inner surface thereof. Hereinafter, various example embodiments of the inventive concepts will be described in detail with reference to drawings and the like.

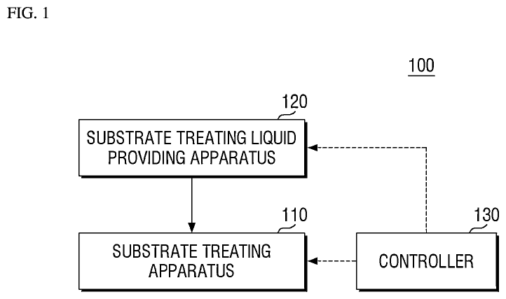

FIG. 1 is a block diagram illustrating internal components of a substrate treating system utilized in a cleaning process. As illustrated in FIG. 1, a substrate treating system 100 may include a substrate treating apparatus 110, a substrate treating liquid providing apparatus 120, and/or a controller 130, etc., but the example embodiments are not limited thereto, and for example, the substrate treating system 100 may include a greater or lesser number of constituent components.

The substrate treating apparatus 110 treats at least one substrate (e.g., a semiconductor wafer, etc.) using at least one chemical, liquid, substance, gas, plasma, etc. Such a substrate treating apparatus 110 may be provided as a cleaning process chamber cleaning the substrate using the chemical, but is not limited thereto.

The chemical may be a liquid material (e.g., an organic solvent, etc.) and/or a gaseous material, etc., but is not limited thereto. The chemical may include materials having high volatility, may generate a large amount of fumes and/or may have high residual properties due to high viscosity, etc. The chemical may be at least one of, for example, a material including an isopropyl alcohol (IPA) component, a material including a sulfuric acid component (e.g., a sulfuric peroxide mixture (SPM) including a sulfuric acid component and a hydrogen peroxide component), a material including an ammonia water component (e.g., SC-1(H₂O₂+NH₄OH) and a material including a hydrofluoric acid component (e.g., diluted hydrogen fluoride (DHF)), a material including a phosphoric acid component, and the like, but the example embodiments are not limited thereto. Hereinafter, these chemicals used to process the substrate will be defined as substrate treating liquids.

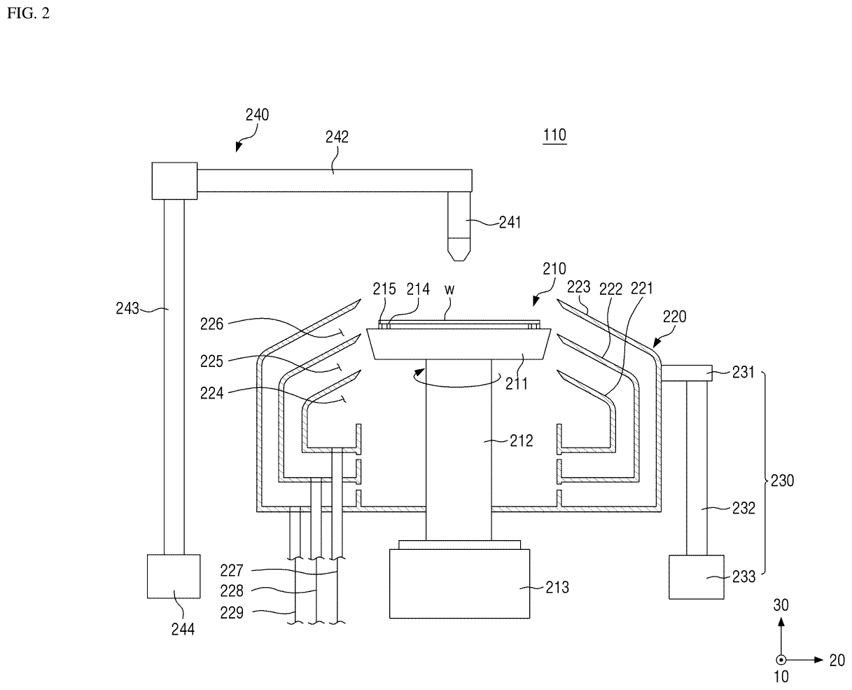

As described above, when the substrate treating apparatus 110 is applied to the cleaning process, the substrate treating apparatus 110 may rotate the substrate using a spin head and provide the chemical to the substrate using and/or via at least one nozzle. When the substrate treating apparatus 110 is provided as a liquid treating chamber as described above, the substrate treating apparatus 110 may include a substrate support unit 210 (e.g., a substrate support, a substrate support device, etc.), a treating liquid recovery unit 220 (e.g., a treating liquid recovery chamber, a treating liquid recovery vessel, a treating liquid recovery container, etc.), an elevating unit 230 (e.g., an elevating device, an elevating platform, etc.), and/or a discharging unit 240 (e.g., a discharging device, a discharging structure, a discharge pipe, etc.), etc., as illustrated in FIG. 2, but the example embodiments are not limited thereto.

FIG. 2 is an illustrative view schematically illustrating an internal structure of a substrate treating apparatus utilized in a cleaning process. Hereinafter, a description will be provided with reference to FIG. 2.

The substrate support unit 210 (e.g., a substrate support, a substrate support device, etc.) is a structure and/or module which supports at least one substrate W. The substrate support unit 210 may rotate the substrate W in directions (a first direction 10 and/or a second direction 20) perpendicular to a third direction 30 when the substrate W is being treated. The substrate support unit 210 may be inside the treating liquid recovery unit 220 in order to recover at least one substrate treating liquid used for treating the substrate W, but is not limited thereto.

The substrate support unit 210 may include a spin head 211, a rotation shaft 212, a rotation driving module 213 (e.g., a rotation driver, a rotation driving device, etc.), one or more support pins 214, and/or one or more guide pins 215, but is not limited thereto.

The spin head 211 rotates along rotation directions (e.g., the directions perpendicular to the third direction 30) of the rotation shaft 212. Such a spin head 211 may have the same shape as that of the substrate W. However, the example embodiments are not limited thereto. For example, according to at least one other example embodiment, the spin head 211 may have a shape different from that of the substrate W.

The rotation shaft 212 generates a torque using energy provided from the rotation driving module 213. According to at least one example embodiment, the rotation driving module 213 may be implemented as a motor, actuator, etc., but is not limited thereto. Such a rotation shaft 212 may be coupled to each of the rotation driving module 213 and the spin head 211 to transfer the torque by the rotation driving module 213 to the spin head 211, but is not limited thereto, and for example, may be coupled to one or more intermediate gears which are attached to the rotation driving module 213 and/or the spin head 211, etc. The spin head 211 rotates along the rotation axis of the rotation shaft 212, and in this case, the substrate W seated on the spin head 211 may also rotate together with the spin head 211.

The one or more support pins 214 and/or the one or more guide pins 215 fix a position of the substrate W on the spin head 211, or in other words, attach and/or connect the substrate W to the spin head 211, etc. To this end, the support pins 214 support a lower surface of the substrate W on the spin head 211, and the guide pins 215 support side surfaces of the substrate W, but are not limited thereto. A plurality of support pins 214 and a plurality of guide pins 215 may be installed on the spin head 211, but the example embodiments are not limited thereto.

For example, the support pins 214 may have an annular ring shape as a whole, but are not limited thereto. The support pins 214 may support the lower surface of the substrate W so that the substrate W may be spaced apart from an upper portion of the spin head 211 by a desired and/or predetermined distance through the support pins 214, but are not limited thereto.

For example, the guide pins 215 may be chucking pins, and may support the substrate W so that the substrate W does not deviate from its original position when the spin head 211 rotates, but are not limited thereto.

The treating liquid recovery unit 220 recovers the substrate treating liquid used to treat the substrate W. The treating liquid recovery unit 220 may be installed to surround the substrate support unit 210, and accordingly, may provide and/or define a space and/or volume in which a treating process for the substrate W is performed.

When the substrate W starts to rotate by the substrate support unit 210 after it is seated and fixed on the substrate support unit 210, the discharging unit 240 may discharge the substrate treating liquid onto the substrate W according to and/or based on the control (e.g., at least one control signal, etc.) of the controller 130. In this case, due to a centrifugal (and/or a centripetal) force generated by the torque of the substrate support unit 210, the substrate treating liquid discharged onto the substrate W may be dispersed in a direction in which the treating liquid recovery unit 220 is positioned. In this case, the treating liquid recovery unit 220 may recover the substrate treating liquid when the substrate treating liquid flows into the treating liquid recovery unit 220 through inlets (e.g., at least one first opening 224 of a first recovery container 221, a t least one second opening 225 of the second recovery container 222, and/or a t least one third opening 226 of a third recovery container 223, etc., to be described later).

The treating liquid recovery unit 220 may include a plurality of recovery containers. The treating liquid recovery unit 220 may include, for example, three recovery containers, but is not limited thereto, and may include a greater or lesser number of recovery containers. When the treating liquid recovery unit 220 include the plurality of recovery containers as described above, the treating liquid recovery unit 220 may separately recover the substrate treating liquid used in a substrate treating process using one or more of the plurality of recovery containers, and accordingly, the substrate treating liquid may be recycled.

When the treating liquid recovery unit 220 includes three recovery containers, the treating liquid recovery unit 220 may include a first recovery container 221, a second recovery container 222, and a third recovery container 223, but is not limited thereto. The first recovery container 221, the second recovery container 222, and the third recovery container 223 may be implemented as, for example, bowls (e.g., a circular shape, etc.), but is not limited thereto, and for example, may have a cylindrical shape, a rectangular shape, an elliptical shape, a polygonal shape, etc.

The first recovery container 221, the second recovery container 222, and/or the third recovery container 223 may recover different substrate treating liquids, etc. For example, the first recovery container 221 may recover a rinsing liquid (e.g., deionized (DI) water), the second recovery container 222 may recover a first chemical, and the third recovery container 223 may recover the second chemical, etc.

The first recovery container 221, the second recovery container 222, and the third recovery container 223 may be connected to a plurality of recovery lines, e.g., recovery lines 227, 228, and 229, etc., extending in a downward direction (that is, third direction 30) from bottom surfaces thereof, respectively, but the example embodiments are not limited thereto. A plurality of treating liquids and/or substances, such as a first treating liquid, a second treating liquid, and/or a third treating liquid, etc., recovered through the first recovery container 221, the second recovery container 222, and/or the third recovery container 223, etc., respectively, may be treated to be reusable through in a treating liquid regeneration system (not illustrated).

The first recovery container 221, the second recovery container 222, and/or the third recovery container 223 may have an annular ring shape in which they surround the substrate support unit 210, but are not limited thereto, and for example, may have non-annular ring shapes, and/or one or more of the recovery containers may have a different shape than the remaining recovery containers. Sizes of the first recovery container 221, the second recovery container 222, and the third recovery container 223 may increase from the first recovery container 221 toward the third recovery container 223 (e.g., in the second direction 20). When an interval between the first recovery container 221 and the second recovery container 222 is defined as a first interval and an interval between the second recovery container 222 and the third recovery container 223 is defined as a second interval, the first interval may be the same as the second interval. However, the example embodiments are not limited thereto. The first interval may also be different from the second interval. That is, the first interval may be greater than the second interval or be smaller than the second interval.

The elevating unit 230 linearly moves the treating liquid recovery unit 220 in a vertical direction (e.g., the third direction 30). The elevating unit 230 may serve to adjust a relative height of the treating liquid recovery unit 220 with respect to the substrate support unit 210 (and/or the substrate W) through the linear movement.

The elevating unit 230 may include at least one bracket 231, at least one first support shaft 232 and/or at least one first driving module 233, etc., but is not limited thereto. According to at least one example embodiment, the first driving module 233 may be implemented as a motor, actuator, etc., but is not limited thereto.

The bracket 231 is fixed to an outer wall of the treating liquid recovery unit 220. The bracket 231 may be coupled to the first support shaft 232 and may be moved in the vertical direction by the first driving module 233.

When the substrate W is seated on the substrate support unit 210, the substrate support unit 210 may be positioned at a level higher than the treating liquid recovery unit 220, but is not limited thereto. Similarly, even when the substrate W is detached from the substrate support unit 210, the substrate support unit 210 may be positioned at a level higher than the treating liquid recovery unit 220, but is not limited thereto. In such a case, the elevating unit 230 may serve to lower the treating liquid recovery unit 220, etc.

When the treating process for the substrate W is performed, the corresponding treating liquid may be recovered by any one of the first recovery container 221, the second recovery container 222, and/or the third recovery container 223 according to and/or based on a type of the substrate treating liquid discharged onto the substrate W, etc., but is not limited thereto. Also in such a case, the elevating unit 230 may serve to elevate the treating liquid recovery unit 220 up to a corresponding position. For example, when the first treating liquid is used as the substrate treating liquid, the elevating unit 230 may elevate the treating liquid recovery unit 220 so that the substrate W is positioned at a height corresponding to the first opening 224 of the first recovery container 221, etc.

Meanwhile, in at least one example embodiment, the elevating unit 230 may also adjust the relative height of the treating liquid recovery unit 220 with respect to the substrate support unit 210 (and/or the substrate W) by linearly moving the substrate support unit 210 in the vertical direction.

However, the example embodiments are not limited thereto. The elevating unit 230 may also adjust the relative height of the treating liquid recovery unit 220 with respect to the substrate support unit 210 (and/or the substrate W) by linearly moving the substrate support unit 210 and the treating liquid recovery unit 220 simultaneously in the vertical direction, etc.

The discharging unit 240 is a module that supplies, ejects, emits, expels, sprays, etc., the substrate treating liquid onto the substrate W at the time of treating the substrate W, but is not limited thereto, and for example, may eject a gaseous substance and/or plasma substance, etc. At least one such discharging unit may be installed in the substrate treating apparatus 110. When a plurality of discharging units 240 are installed in the substrate treating apparatus 110, the respective discharging units may discharge different substrate treating liquids onto the substrate W.

The discharging unit 240 may include at least one nozzle 241, at least one nozzle support module 242, at least one second support shaft 243 and/or at least one second driving module 244, etc., but is not limited thereto. According to at least one example embodiment, the second driving module 244 may be implemented as a motor, actuator, etc., but is not limited thereto.

The nozzle 241 is installed at an end portion of the nozzle support module 242. The nozzle 241 may be moved to at least one process position and/or a standby position by the second driving module 244, but is not limited thereto.

Here, the process position refers to a region above the substrate W, and the standby position refers to a region other than the process position. The nozzle 241 may be moved to the process position when it discharges the substrate treating liquid onto the substrate W, and may leave the process position and be moved to the standby position after it discharges the substrate treating liquid onto the substrate W.

The nozzle support module 242 (e.g., nozzle support structure, nozzle support device, nozzle support apparatus, etc.) supports the nozzle 241. Such a nozzle support module 242 may be formed to extend in a direction corresponding to a length direction of the spin head 211, but is not limited thereto. That is, a length direction of the nozzle support module 242 may be provided along the second direction 20, etc.

The nozzle support module 242 may be coupled to the second support shaft 243 extending in a direction perpendicular to the length direction thereof. The second support shaft 243 may be formed to extend in a direction corresponding to a height direction of the spin head 211. That is, a length direction of the second support shaft 243 may be provided along the third direction 30.

The second driving module 244 is a module that rotates and/or elevates the second support shaft 243, and the nozzle support module 242 moving together with the second support shaft 243. According to such a function of the second driving module 244, the nozzle 241 may be moved to the process position and/or to the stand-by position, etc.

A description will be provided with reference to FIG. 1 again.

The substrate treating liquid providing apparatus 120 provides the substrate treating liquid, etc., to the substrate treating apparatus 110. To this end, the substrate treating liquid providing apparatus 120 may be connected to the discharging unit 240 of the substrate treating apparatus 110 and may operate according to and/or based on the control of the controller 130, e.g., via control signals and/or instructions provided by and/or generated by the controller 130, etc.

The controller 130 controls at least one operation of the substrate treating apparatus 110. Specifically, the controller 130 may control operations of the rotation driving module 213 of the substrate support unit 210, the first driving module 233 of the elevating unit 230, and/or the second driving module 244 of the discharging unit 240, etc.

The controller 130 may be implemented as a computer, a server, or the like, including at least one process controller, at least one control program, an input device, an output device (and/or a display device), a memory device, and the like. According to at least one example embodiment, the controller 130 may be implemented as processing circuitry and the processing circuitry may include hardware including logic circuits; a hardware/software combination such as a processor executing software and/or firmware; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc., but is not limited thereto. For example, the process controller may include a microprocessor executing a control function for respective components constituting the substrate treating apparatus 110, and the control program may execute various treatments of the substrate treating apparatus 110 according to and/or based on the control of the process controller. The memory module (e.g., RAM, ROM, SSD, hard drive, and/or any other type of non-transitory computer readable medium, etc.) stores a program including computer readable instructions for executing various treatments of the substrate treating apparatus 110 according to various data and treating conditions, e.g., a treating recipe, etc.

Meanwhile, the controller 130 may also control at least one operation of the substrate treating liquid providing apparatus 120 so that the substrate treating liquid may be supplied from the substrate treating liquid providing apparatus 120 to the substrate treating apparatus 110 when desired and/or necessary, etc.

When fabricated integrated circuits of the substrate are subjected to a wet and/or dry etching process, particles, organic materials, or the like, remain on a surface of the substrate, at least one process of cleaning the particles, the organic materials, or the like, with deionized water is performed, and a sub-unit process finished by drying moisture on the substrate is then performed. In this case, when the moisture is not completely removed, the formation of the circuits is hindered, which has an influence on the yield of semiconductor elements and/or operation of the semiconductor elements, etc.

In general, a process of drying the moisture of the substrate is divided into two methods such as a method of rotating the spin head 211 at a high speed (e.g., 1500 rpm to 2000 rpm, but not limited thereto), and treating the moisture with a centrifugal force (and/or centripetal force) and a method of discharging a second liquid, e.g., isopropyl alcohol (IPA), etc., having a lower surface tension than water onto the substrate to allow the moisture to be replaced with the second liquid (e.g., IPA) and be dried. In the above, the former method has difficulty in completely removing the moisture, and thus, the latter method has been mainly used to remove the moisture.

However, in the case of the latter method, that is, a method of removing the moisture of the substrate using the second liquid (e.g., IPA), a nozzle of which an inner surface of a pipe is smoothly is used as an IPA discharging nozzle, and due to characteristics of the IPA discharging nozzle, even though a process of discharging the IPA onto the substrate W is finished, the IPA remaining in the IPA discharging nozzle flows down to the surface of the substrate W, such that the fabricated integrated circuits on the substrate are not completely dried, resulting in a side effect of decreasing a yield of the semiconductor elements, etc.

Accordingly, in the at least one example embodiment, in order to decrease and/or solve the problem as described above, a nozzle of the discharging unit 240 capable of decreasing and/or preventing a chemical from flowing down by having a roughness and/or surface roughness formed on an inner surface thereof is provided. Hereinafter, this will be described in detail.

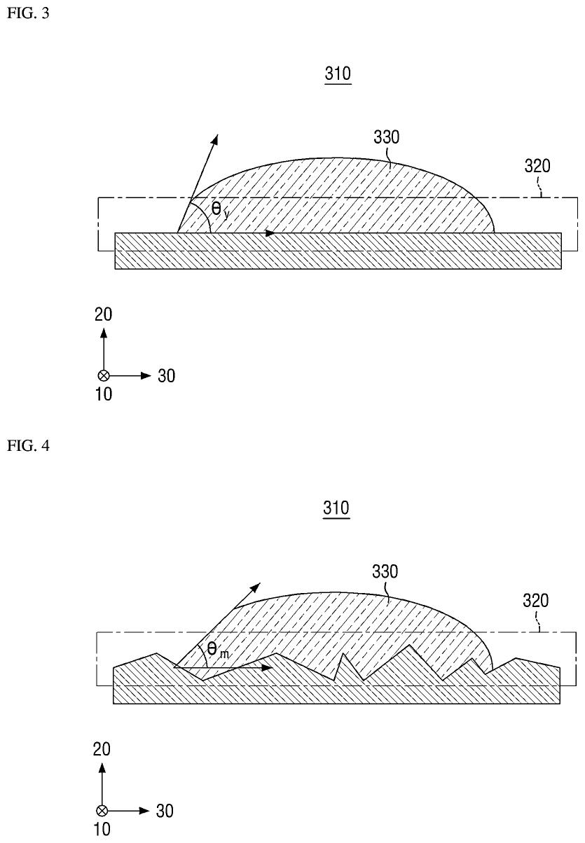

At least one drop (e.g., undesired leak, expulsion, etc.) of the chemical may occur due to a potential difference between the substrate W and a tip of the nozzle. However, when an inner surface 320 of the tip 310 of the nozzle is smoothly formed as illustrated in FIG. 3, an adhesive force between the inner surface 320 of the tip 310 and the chemical 330 may be decreased, and consequently, flowing down of the chemical 330 may more easily occur. FIG. 3 is a first illustrative view for describing a relationship between an internal structure of the nozzle and a surface adhesive force of the chemical.

In at least one example embodiment, as illustrated in FIG. 4, surface roughness is imparted to, formed on, added to, and/or etched into, the inner surface 320 of the tip 310 of the nozzle to enhance an adhesive force between the inner surface 320 of the tip 310 and the chemical 330, and accordingly, it is possible to prevent the chemical 330 from flowing down. In particular, the at least one example embodiment is characterized by improving, increasing and/or optimizing the surface roughness inside the tip 310 to increase, improve, and/or maximize the adhesive force between the inner surface 320 of the tip 310 and the chemical 330. FIG. 4 is a second illustrative view for describing a relationship between an internal structure of the nozzle and a surface adhesive force of the chemical.

In the above, the nozzle in which the surface roughness is imparted, imprinted, added, etc., to the inner surface 320 of the tip 310 is a nozzle discharging the chemical from among a plurality of nozzles included in the discharging unit 240. Specifically, the nozzle in which the surface roughness is included on the inner surface 320 of the tip 310 is a nozzle discharging at least one chemical having a lower surface tension than water. More specifically, the nozzle in which the surface roughness is included on the inner surface 320 of the tip 310 is a nozzle discharging the IPA, but the example embodiments are not limited thereto. In the case of the IPA, as the roughness of the surface increases, a contact angle may be decreased and a surface adhesive force of the IPA to the inner surface 320 of the tip 310 may be increased.

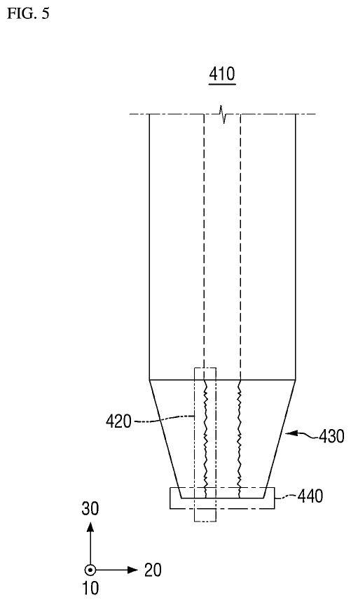

As described above, in a nozzle 410 discharging the chemical, at least one pattern 420 (e.g., a surface pattern, etc.) imparting roughness and/or surface roughness to an inner portion of the nozzle 410 may be formed on a partial surface, area, and/or location inside the nozzle 410, but the example embodiments are not limited thereto. For example, the pattern 420 may be formed at a distal end 430 of the nozzle 410 adjacent to a discharge port 440 as illustrated in FIG. 5, but is not limited thereto. In the above, the distal end 430 may refer to a tip of the nozzle 410. FIG. 5 is a first illustrative view schematically illustrating an internal structure of the nozzle according to at least one example embodiment of the inventive concepts.

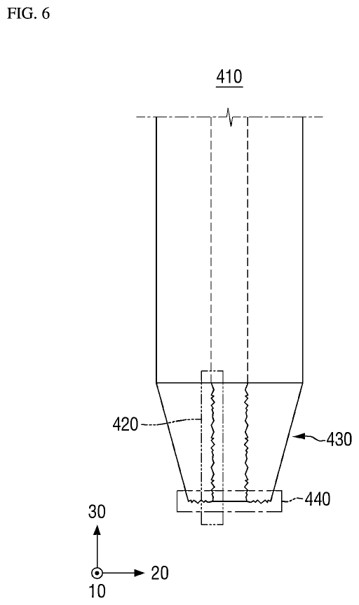

However, the example embodiment are not limited thereto. In the nozzle 410 discharging the chemical, the pattern 420 including the surface roughness to the inner portion of the nozzle 410 may be located and/or formed not only at the distal end 430 of the nozzle 410 adjacent to the discharge port 440 but also on other surfaces, areas, and/or locations of the nozzle 410, such as a surface of the discharge port 440, as illustrated in FIG. 6, but the example embodiments are not limited thereto. FIG. 6 is a second illustrative view schematically illustrating an internal structure of the nozzle according to at least one example embodiment of the inventive concepts.

Meanwhile, the example embodiments are not limited thereto, and the pattern 420 imparting surface roughness may also be formed, for example, on the entire surface of the inner portion of the nozzle 410, etc.

In the nozzle 410 discharging the chemical, the pattern 420 imparting the surface roughness to the inner portion of the nozzle 410 may include and/or be formed as an irregular pattern as illustrated in FIGS. 5 and 6, but the example embodiments are not limited thereto. Here, the irregular pattern refers to a plurality of projections providing the surface roughness to the inner portion of the nozzle 410 that do not have a constant shape, but the example embodiments are not limited thereto.

However, the example embodiments are not limited thereto. In the nozzle 410 discharging the chemical, the pattern 420 imparting the surface roughness to the inner portion of the nozzle 410 may be formed as, e.g., a regular pattern, a constant pattern, etc. That is, a plurality of projections providing surface roughness inside the nozzle 410 may have a constant shape, but are not limited thereto. For example, a regular pattern 510 may be a pattern in which A-shaped projections are continuously formed, but the example embodiments are not limited thereto.

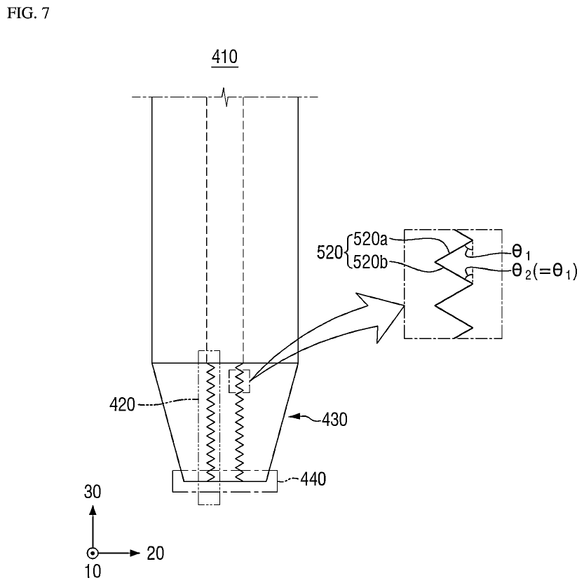

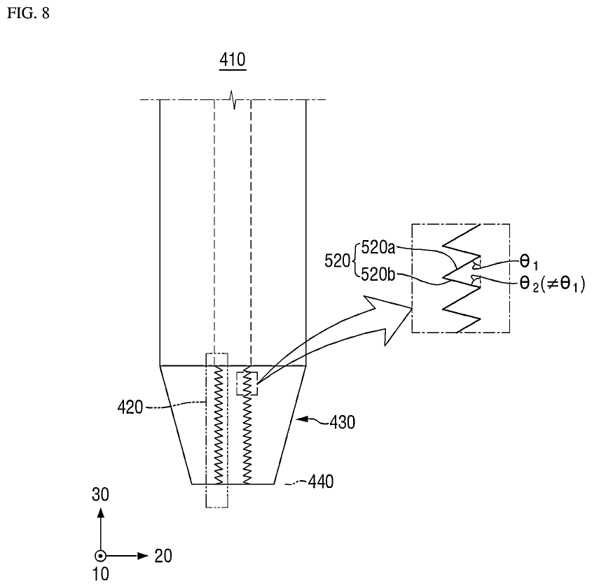

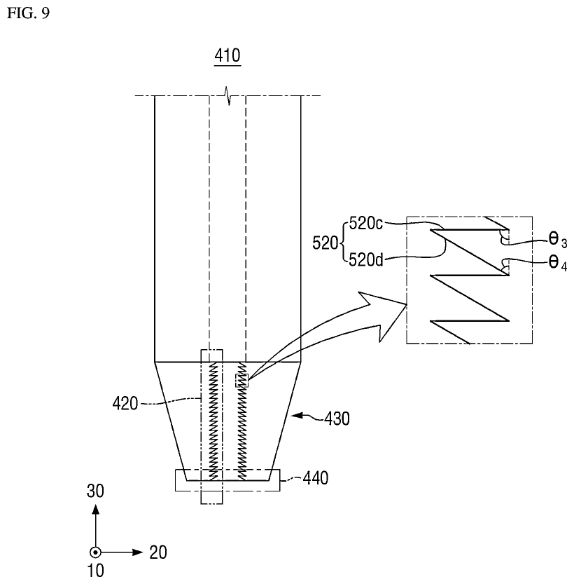

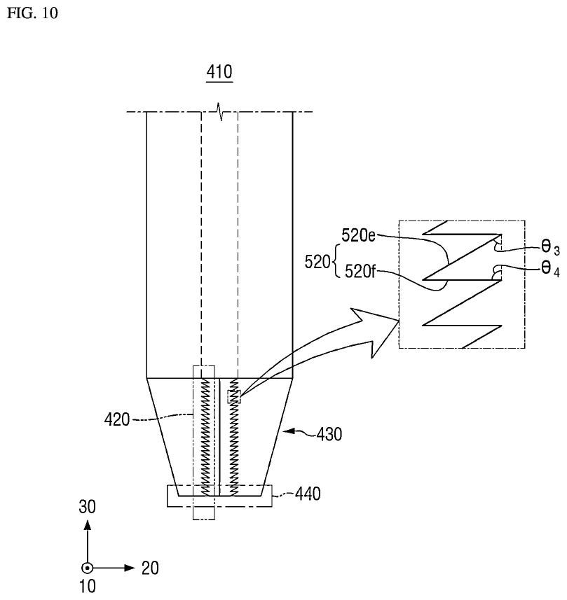

In this case, the regular pattern 510 may have both inclined surfaces as illustrated in FIGS. 7 and 8, but are not limited thereto. Additionally, the regular pattern 510 may have one inclined surface as illustrated in FIGS. 9 and 10, etc.

When a plurality of projections included in the regular pattern 510 have at least two inclined surfaces (e.g., both surfaces are inclined, etc.), the two inclined surfaces of the projections may be formed at the same angle, but the example embodiments are not limited thereto. Specifically, when any one projection 520 of the plurality of projections constituting the regular pattern 510 includes a first inclined surface 520a and a second inclined surface 520b, the first inclined surface 520a may be formed along an ascending curved line or an ascending straight line, and the second inclined surface 520b may be formed along a descending curved line or a descending straight line, etc. Here, an inclination angle θ₁ (e.g., 0°<θ₁<90°) of the first inclined surface 520a may be the same as an inclination angle θ₂ (e.g., 0°<θ₂<90) of the second inclined surface 520b (e.g., θ₁=θ₂), as illustrated in FIG. 7, but the example embodiments are not limited thereto.

An example of FIG. 7 is an example of a case where the first inclined surface 520a is along (and/or formed along) the ascending straight line and the second inclined surface 520b is along (and/or formed along) the descending straight line, but the example embodiments are not limited thereto. FIG. 7 is a third illustrative view schematically illustrating an internal structure of the nozzle according to at least one example embodiment of the inventive concepts.

When a plurality of projections included in the regular pattern 510 have at least two inclined surfaces, the two inclined surfaces of the projections may have, and/or may also be formed at, different angles. For example, when any one projection 520 of the plurality of projections included in the regular pattern 510 includes a first inclined surface 520a and a second inclined surface 520b, the first inclined surface 520a may be along (and/or formed along) an ascending curved line and/or an ascending straight line, and the second inclined surface 520b may be along (and/or formed along) a descending curved line and/or a descending straight line, etc. Here, an inclination angle θ₁ (e.g., 0°<θ₁<90°) of the first inclined surface 520a may be different from an inclination angle θ₂ (e.g., 0°<θ₂<90) of the second inclined surface 520b (θ₁≠θ₂), as illustrated in FIG. 8, but the example embodiments are not limited thereto.

FIG. 8 is an example of a case where the first inclined surface 520a is along (and/or formed along) the ascending straight line and the second inclined surface 520b is along (and/or formed along) the descending straight line, but the example embodiments are not limited thereto. FIG. 8 is a fourth illustrative view schematically illustrating an internal structure of the nozzle according to at least one example embodiment of the inventive concepts.

When a plurality of projections included in the regular pattern 510 have one inclined surface (e.g., a single inclined surface, etc.), the inclined surface may be along (and/or formed along) a descending curved line and/or a descending straight line. Specifically, any one projection 520 of the plurality of projections including the regular pattern 510 may include a first vertical surface 520c and/or a third inclined surface 520d, etc. As illustrated in FIG. 9, the first vertical surface 520c may be along (and/or formed along) an ascending straight line, and the third inclined surface 520d may be along (and/or formed along) a descending curved line and/or a descending straight line, but the example embodiments are not limited thereto.

An inclination angle θ₃ (e.g., θ₃=90°) of the first vertical surface 520c has a value greater than an inclination angle θ₄ (e.g., 0°<θ₄<90°) of the third inclined surface 520d, but the example embodiments are not limited thereto. FIG. 9 is an example of a case where the first vertical surface 520c is formed along the ascending straight line and the third inclined surface 520d is formed along the descending straight line, but the example embodiments are not limited thereto. FIG. 9 is a fifth illustrative view schematically illustrating an internal structure of the nozzle according to at least one example embodiment of the inventive concepts.

When a plurality of projections included in the regular pattern 510 have one inclined surface, the inclined surface may along (and/or be formed along) an ascending curved line and/or an ascending straight line, etc. Specifically, any one projection 520 of the plurality of projections included in the regular pattern 510 may include a fourth inclined surface 520e and/or a second vertical surface 520f, etc. As illustrated in FIG. 10, the fourth inclined surface 520e may be along (and/or formed along) an ascending curved line and/or an ascending straight line, and/or the second vertical surface 520f may be along (and/or formed along) a descending straight line, etc.

An inclination angle θ₄ (e.g., θ₄=90°) of the second vertical surface 520f has a value greater than an inclination angle θ₃ (e.g., 0°<θ₃<90°) of the fourth inclined surface 520e, but are not limited thereto. FIG. 10 is an example of a case where the fourth inclined surface 520e is formed along the ascending straight line and the second vertical surface 520f is formed along the descending straight line, but the example embodiments are not limited thereto. FIG. 10 is a sixth illustrative view schematically illustrating an internal structure of the nozzle according to at least one example embodiment of the inventive concepts.

Meanwhile, in at least one example embodiment, the regular pattern 510 is not limited to the pattern in which the ∧-shaped projections are continuously formed. That is, the regular pattern 510 may be a pattern in which other projections, such as semicircular projections, etc., are continuously formed. Additionally, the regular pattern 510 may be a pattern in which semi-elliptical projections are continuously formed, etc. Additionally, the regular pattern 510 may be a pattern in which polygonal projections are continuously formed, etc.

At least one example embodiment relates to an improved discharging unit 240 of the substrate treating apparatus 110 which removes moisture after a wet cleaning process during a manufacturing (e.g., fabricating) process of the substrate W. At least one example embodiment provides an improved nozzle 410 so that a residual IPA treating liquid of the discharging unit 240 does not flow down (e.g., leaks, etc.) to the substrate W during a drying process of the substrate W. In the case of the nozzle 410 which discharges the chemical (e.g., IPA) among a plurality of nozzles 241 constituting the discharging unit 240, it may be a benefit and/or important in the example embodiments of the inventive concepts to increase the adhesive force of the IPA so that the treating liquid does not flow down after the discharging of the treating liquid onto the substrate W has been completed.

At least one example embodiment of the inventive concepts provides a substrate drying and treating apparatus, but the example embodiments are not limited thereto. According to at least one example embodiment of the inventive concepts, a space capable of treating the substrate W may be provided, the spin head 211 supporting the loaded substrate W may rotate, the discharging unit 240 discharging the treating liquid onto the substrate W may be included, and a desired and/or certain level of roughness may be on (and/or formed on) an inner surface of the nozzle 410 discharging the chemical in the discharging unit 240.

According to at least one example embodiment, the pattern providing the roughness may be formed on and/or located on a portion (e.g., a tip) of the nozzle 410 and/or uniformly formed inside the nozzle 410, but the example embodiments are not limited thereto. According to at least one example embodiment, the pattern providing the roughness is obtained by injection-molding a hole penetrating through an inner portion of the nozzle 410 and/or is obtained by processing the hole after the injection-molding, but the example embodiments are not limited thereto.

According to at least one example embodiment, the roughness may be based on the Wenzel's equation which increases the adhesive force between the chemical and the nozzle 410. (Robert N. Wenzel, 1936, Definition of correlation of interface between solid and liquid.)

The Wenzel's equation relates to an adhesive force of an interface between a liquid and a solid, and in particular, defines an adhesive force of an interface between a solid (e.g., the nozzle 410) having roughness and a liquid (e.g., the IPA) in contact with the solid.

The Wenzel's equation represents a theoretical basis for an increase in the adhesive force with the IPA due to a decrease in a contact angle and the surface roughness is inside the nozzle 410. The Wenzel's equation is as follows:

Wa=γL(1+cos θ).

Here, Wa refers to the adhesive force of the chemical to the inner surface of the nozzle 410. In addition, γL refers to a surface tension of the chemical, and θ refers to a contact angle between the inner surface of the nozzle 410 and the chemical.

According to the Wenzel's equation, fluid atoms are stagnant between a plurality of projections providing surface roughness, such that a tensile force between the inner surface of the nozzle and the fluid atoms increases, and drag resistance is increased at an interface between a fluid and a solid due to the surface roughness, such that flowing-down (e.g., leakage, etc.) of the treating liquid is decreased.

According to at least one example embodiment, the roughness will be expressed as a roughness average (Ra), and in at least one example embodiment, the roughness may be manufactured to satisfy a desired value, e.g., 0.4 Ra to 5 Ra, etc., greater than an injection roughness average (e.g., 0.15 Ra or less), but the example embodiments are not limited thereto.

According to at least one example embodiment, the roughness is effective between, e.g., 0.5 Ra and 5 Ra, etc., but it is desirable and/or advantageous in decreasing and/or preventing the IPA from flowing down that the roughness is uniformly manufactured to be formed at a distribution level of 0.5±0.3 Ra, but the example embodiments are not limited thereto. Additionally, it is effective in decreasing and/or preventing the IPA from flowing down that roughness of, e.g., 0.5 Ra to 5 Ra, etc., is given to the inner portion of the nozzle but is uniformly formed with an error of ±0.3 Ra, but the example embodiments are not limited thereto.

According to at least one example embodiment, the nozzle is installed vertically on a surface of the substrate and a size of the inner surface of the nozzle may be freely changed according to and/or based on a substrate treating environment.

According to at least one example embodiment, various treating methods may be applied according to the particularity of the art. The inner surface of the nozzle may be subjected to a manufacturing process of roughening the surface of the nozzle several times, and a method of roughening the surface of the nozzle may be changed depending on particularity of a manufacturing environment in the art.

Meanwhile, after the nozzle is manufactured and a hole through which the chemical passes is formed in the nozzle, a surface of the hole may be smoothed, but in at least one example embodiment, the roughness may be formed on and/or located on the inner surface of the nozzle without such a process. Additionally, in the at least one example embodiment, it is also possible to artificially form the roughness on the inner surface of the nozzle like an irregular pattern or a regular pattern, etc.

According to at least one example embodiment, the surface roughness of the inner surface of the nozzle may be manufactured in an irregular circular shape, but is not limited thereto. The roughness of the inner surface of the nozzle has an irregular shape and may not protrude beyond an average roughness value.

The IPA, which is a substrate drying treating liquid, has a surface tension (e.g., 22 dynes/cm) three or more times lower than a surface tension (e.g., 72 dynes/cm) of water, and due to such characteristics, in an existing smooth nozzle which is vertically installed, even though the supply of the treating liquid has been completed, a flowing-down and/or spray phenomenon of a small amount of IPA may occur. The amount of the flowing-down IPA is affected by the number of revolutions of the spin head 211 and the size of the inner surface of the nozzle, and the flowing-down IPA hinders the formation of semiconductor circuits on a wafer and affects the yield of the wafer.

According to at least one example embodiment, an improvement effect of decreasing and/or preventing the IPA from flowing down by imparting the surface roughness to an internal pipe of the nozzle 410 discharging the chemical to increase the adhesive force of the IPA may be achieved. That is, when the surface roughness of the nozzle 410 becomes a desired and/or predetermined level or more, the adhesive force between the nozzle 410 and the IPA increases, such that the IPA does not flow down to the substrate W after the discharging of the IPA has been completed.

Hereinabove, various example embodiments of the discharging unit 240 including the nozzle discharging the chemical (e.g., the IPA), the nozzle discharging the deionized water (DIW), and the like, and the substrate treating apparatus 110 including the same has been described with reference to FIGS. 1 to 10. In addition, the pattern imparting the surface roughness to the inner surface of the nozzle 410 discharging the chemical has also been described.

In at least one example embodiment, the contact angle of the IPA is decreased by maintaining the surface roughness of the inner portion of the nozzle at a specific level, and accordingly, the dropping and/or leakage of the IPA due to external force may be decreased and/or prevented. The surface roughness may be imparted to the nozzle discharging the chemical, and may not be imparted to the nozzle discharging the deionized water. Additionally, the surface roughness may be imparted to both the nozzle discharging the chemical and the nozzle discharging the deionized water, but surface roughness (Ra) imparted to the nozzle discharging the chemical may have a value greater than surface roughness (Ra) imparted to the nozzle discharging the deionized water, but is not limited thereto. The surface roughness (Ra) imparted to the nozzle discharging the chemical may have a greater value, e.g., 3 to 35 times greater, etc., than the surface roughness (Ra) imparted to the nozzle discharging the deionized water, but the example embodiments are not limited thereto.

Various example embodiments of the inventive concepts have been described hereinabove with reference to the accompanying drawings, but the inventive concepts are not limited to the above-described example embodiments, and may be implemented in various different forms, and one of ordinary skill in the art to which the inventive concepts pertain may understand that the inventive concepts may be implemented in other specific forms without changing the technical concept or features of the inventive concepts. Therefore, it is to be understood that the example embodiments described above are illustrative rather than being restrictive in all aspects.

What is claimed is:

1. A substrate treating apparatus comprising:
a substrate support structure including a spin head, the substrate support structure configured to support a substrate, and rotate the substrate;
at least one treating liquid recovery container configured to recover at least one substrate treating liquid; and
a discharging device including a first nozzle and a second nozzle,
the first nozzle configured to discharge a chemical onto the substrate, and
the second nozzle configured to discharge deionized water onto the substrate, wherein
the first nozzle includes a surface pattern configured to provide roughness on an inner surface of the first nozzle.

2. The substrate treating apparatus of claim 1, wherein the surface pattern is on a portion of the inner surface of the first nozzle.

3. The substrate treating apparatus of claim 1, wherein the surface pattern is on an end portion of the first nozzle adjacent to a discharge port.

4. The substrate treating apparatus of claim 3, wherein the surface pattern is further on a surface of the discharge port.

5. The substrate treating apparatus of claim 1, wherein the surface pattern has a roughness value of 0.4 to 5.

6. The substrate treating apparatus of claim 1, wherein the surface pattern includes a plurality of projections that do not have a constant shape.

7. The substrate treating apparatus of claim 1, wherein the surface pattern includes a plurality of projections that have a constant shape.

8. The substrate treating apparatus of claim 7, wherein each of the projections includes a first inclined surface and a second inclined surface.

9. The substrate treating apparatus of claim 8, wherein
the first inclined surface and the second inclined surface have a same inclination angle.

10. The substrate treating apparatus of claim 8, wherein
the first inclined surface and the second inclined surface have different inclination angles.

11. The substrate treating apparatus of claim 7, wherein each of the projections includes a vertical surface and an inclined surface.

12. The substrate treating apparatus of claim 1, wherein
the surface pattern is obtained by injection-molding a hole penetrating through an inner portion of the first nozzle; or
the surface pattern is obtained by processing the hole after the injection-molding.

13. The substrate treating apparatus of claim 1, further comprising:
a second surface pattern on an inner surface of the second nozzle.

14. The substrate treating apparatus of claim 13, wherein the surface pattern on the inner surface of the first nozzle has a roughness value greater than that of the second surface pattern on the inner surface of the second nozzle.

15. The substrate treating apparatus of claim 1, wherein the chemical is a material having a surface tension lower than that of water.

16. The substrate treating apparatus of claim 1, wherein the chemical is isopropyl alcohol (IPA).

17. The substrate treating apparatus of claim 1, wherein the substrate treating apparatus is further configured to dry the substrate using the chemical.

18. A substrate treating apparatus comprising:
a discharging device including a first nozzle and a second nozzle, the discharging device configured to provide a substrate treating liquid onto a substrate through the first nozzle and the second nozzle, the first nozzle configured to discharge a chemical onto the substrate, and the second nozzle configured to discharge deionized water onto the substrate; and
the first nozzle includes a surface pattern configured to provide surface roughness on an inner surface of the first nozzle,
the surface pattern is on a portion of the inner surface of the first nozzle, and is formed at an end portion of the first nozzle adjacent to a discharge port or is formed at the end portion of the first nozzle and on a surface of the discharge port, and
the surface pattern has a roughness value of 0.4 to 5.

19. A discharging device configured to provide a substrate treating liquid for treating a substrate, comprising:
a first nozzle configured to discharge a chemical onto a substrate;
a second nozzle configured to discharge deionized water on the substrate; and
the first nozzle includes a surface pattern configured to provide surface roughness is on an inner surface of the first nozzle.

20. The discharging device of claim 19, wherein the surface pattern is at an end portion of the first nozzle adjacent to a discharge port, and the surface pattern is on a surface of the discharge port.
